(19) United States
(12) Patent Application Publication
(10) Pub. No.: US 2007/0105262 A1
(43) Pub. Date: May 10, 2007

(54) Method for fabricating an integrated circuit with a CMOS manufacturing process

(75) Inventors: Albert Birner, Dresden (DE); Andreas Weber, Dresden (DE); Olaf Storbeck, Dresden (DE); Michael Stadtmueller, Dresden (DE); Wieland Pethe, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/270,820

(22) Filed: Nov. 10, 2005

(51) Int. Cl. H01L 21/00

(52) U.S. Cl. 438/48

(57) ABSTRACT

An integrated circuit, which is formed on a semiconductor substrate and which comprises front-end-of-line processed electronic elements and a back-end-of-line processed wiring on top of the electronic elements. The wiring interconnects the electronic elements. The integrated circuit further comprises a highly UV-absorbing layer between the electronic elements and the wiring.

### TECHNICAL FIELD OF THE INVENTION

The present invention relates to a method for fabricating an integrated circuit with a CMOS manufacturing process and to an integrated circuit comprising electronic elements and an interconnecting wiring.

### BACKGROUND OF THE INVENTION

Modem integrated electronic circuits contain a myriad of densely packed electronic elements—such as resistors, capacitors or transistors—on a single semiconductor substrate chip. While often millions of such elements form an integrated circuit, nowadays the size of a single chip is far below a squared inch. Over recent years, the semiconductor industry has established very sophisticated and reliable manufacturing processes for routinely fabricating highly integrated circuits, the most prominent member of these processes being the so-called CMOS process.

Integration is very critical and closely related to the overall device performance in electronic data memories. Such electronic data memory devices, for example a dynamic random access memory (DRAM), store their information content in capacitors, these capacitors being operated via so-called selection transistors. One memory cell then comprises at least one capacitor and one transistor. Increasing the performance of an electronic data memory accordingly translates to integrating as many capacitors and transistors as possible in a substrate chip of a given—and limited—size. Similar requirements also apply to related types of electronic integrated devices, for example, to microprocessors or to other highly integrated electronic circuitries.

A CMOS process, comprising hundreds of single process stages, may be divided up into three main sections: A front-end-of-line (FEOL), a mid-of-line (MOL), and a back-end-of-line (BEOL). The manufacturing of a highly integrated circuit by a CMOS process is usually conducted as follows, and described here—as an example—for a DRAM: During the first FEOL section, electronic entities, such as capacitors, transistors, and access gates are formed on a semiconductor substrate. The latter access gate is also referred to as the gate stack, since the access gate usually comprises a stack of different materials.

During the following MOL section of a CMOS process, several isolation layers are formed, in order to prevent the diffusion of dopant materials or undesired electrical contact between the electronic entities and the circuit wiring. This wiring is subsequently provided during the last stage, the BEOL of the CMOS process, which usually commences with the first metallization after the MOL.

During this BEOL of a typical CMOS process, several plasma processes are conducted for etching and deposition purposes. While plasma enhanced etching and deposition techniques offer a wide range of benefits, they also give rise to intense electromagnetic radiation. High energy electromagnetic radiation, above all ultraviolet light with wavelengths below 400 nm, may cause disadvantageous modifications and alterations of the very sensitive electronic elements, being formed during the FEOL.

A common problem is that ultraviolet light induces an increased density of electronic states at semiconductor-insulator interfaces, or—in general—at all interfaces of two facing materials that possess different electronic properties. This locally enhanced density of states may cause generation/recombination currents via a combination of tunneling and field emission. Since integrated electronic entities become more and more sensitive upon miniaturization as far as signal accuracy is concerned, such effects are very undesirable. Above all, an uncontrolled increase of the density of states may interfere with capacitors and transistors to cause the destruction of memory content or severe limitations of the reliable operation of the electronic entities of a memory device. Particularly, the so-called data retention time of an electronic memory device may be drastically reduced, said retention time being defined as the time span a memory cell may reliably store a respective logical state.

State of the art CMOS processing of integrated circuits is therefore subject to certain limitations, regarding the integration of more electronic elements onto a given substrate. Maintaining a minimum size of the electronic entities may compensate for the effects of an uncontrolled local density of states, and the resulting noise in signal levels can be avoided. For further increasing the integration of electronic circuits however, this minimum size of the electronic entities cannot be maintained any longer, and, as a consequence, sources of undesired currents and noise have to be eliminated.

### SUMMARY OF THE INVENTION

The present invention provides an improved integrated circuit comprising electronic elements and a wiring and a method for fabricating an improved integrated circuit with a CMOS manufacturing process.

According to one embodiment of the present invention, there is a method for fabricating an integrated circuit wherein the method includes steps as described in the following. In an initial step, a semiconductor substrate is provided for forming an integrated circuit. The forming of the circuit is usually conducted by a combination of lithographic, etching, deposition, and other related techniques. While a substantial fraction of the integrated circuit will be formed on top of the semiconductor substrate during the subsequent method stages, parts of the integrated circuit may be also formed within the semiconductor substrate.

In a second step, electronic elements are formed by means of a front-end-of-line (FEOL) processing of the semiconductor substrate. The last deposition of a diffusion barrier before the wiring is formed initiates the MOL, whereas processing steps prior to the deposition of the diffusion barrier are included by the FEOL. Other covering isolation elements may be deposited during the MOL processing subsequent to the FEOL.

In a next step, a highly UV absorbing layer is provided on the semiconductor substrate for absorbing ultra violet (UV) light, wherein the highly UV absorbing layer covers the electronic elements and screens the underlying electronic elements from high energy light.

The high energy light may cause disadvantageous modifications of the electronic elements, above all the generation of an enhanced localized density of electronic states preferably at interfaces of two facing materials with different electronic properties, such as an insulator and a semiconductor. Undesired currents may result through these localized regions, these currents reducing the reliability and the overall performance of the integrated circuit. UV light is often a by-product of process stages of the subsequent mid-of-line (MOL) and back-end-of-line (BEOL) processing. During the latter, a wiring of the electronic elements is provided on the semiconductor substrate, the substrate then already comprising the electronic elements and the highly UV absorbing layer.

Providing the wiring, and MOL and BEOL processing in general, may comprise steps during which the semiconductor substrate—including the electronic elements—is exposed to ultra violet light. A common example for such steps are plasma enhanced process steps. The plasma enhanced steps, such as plasma enhanced chemical vapor deposition (PECVD) or reactive ion etching (RIE), generate ultra violet light as a by-product of their genuine deposition or etching purpose.

According to the another embodiment of the present invention, the highly UV absorbing layer blocks high energy ultra violet light, and hence reduces undesired modifications of the functionalized parts of the semiconductor substrate and underlying electronic elements. With the inventive method, an integrated circuit with an increased reliability and an enhanced overall circuit performance may be fabricated, applying a standard CMOS process while not having to avoid process steps that generate ultra violet light.

According to another embodiment of the present invention, there is a method for fabricating an integrated memory device, including the following steps. In a first step a semiconductor substrate is provided, on which the integrated memory device is formed by means of lithographic, deposition, etching, and other relating techniques.

In a next step, an FEOL processing of the semiconductor substrate is conducted to form memory cells. Each memory cell includes a capacitor element and a transistor element, wherein the entire capacitor element and transistor element, or parts thereof, may be formed within the semiconductor substrate.

A next step provides a diffusion barrier, wherein the diffusion barrier covers the memory cells. Since electronic entities, such as the capacitor elements or the transistor elements, may be damaged by diffusion of certain elements, undesired diffusion should be blocked. The diffusion barrier is formed after and above the memory cells.

In a next step of the invention, a highly UV absorbing layer is provided on the semiconductor substrate, for blocking, or, at least, substantially attenuating ultra violet light which may be generated during BEOL processing. The highly UV absorbing layer is arranged adjacent to the diffusion barrier.

In a subsequent BEOL processing of the semiconductor substrate, which then already comprises the memory cells, the diffusion barrier, and the highly UV absorbing layer, a wiring of the memory cells is provided. This wiring is for interconnection of the memory cells and additional electronic entities, which are necessary for operation of an integrated memory device.

The wiring also grants access for reading and writing the logical state of a memory cell by means of electric signals.

The memory cells, comprising capacitor and transistor elements in and on top of the semiconductor substrate, may be sensitive to ultra violet light. A spatially enhanced electronic density of states may result in undesired generation/recombination currents via a combination of tunneling and field emission, these currents causing a diminished data retention time. This time is a figure of how long a logical state can be kept reliably in a memory cell and should comply with a given minimum time for a given memory device layout. A reduction of the data retention time of a memory device reduces substantially its reliability.

The highly UV absorbing layer, provided by the inventive fabrication method, allows for the fabrication of an integrated memory device with a process that also includes MOL/BEOL processing, however. During the MOL and BEOL processing ultra violet light may be generated, but, since the highly UV absorbing layer blocks ultra violet light, the structure size of the memory's electronic elements may still be reduced. Hence the reliability and the overall performance of the integrated memory device may be enhanced, while not having to avoid an established and, therefore, very efficient fabrication process.

According to a still another embodiment of the present invention, a method for fabricating an integrated memory device is provided that includes the following steps. In a first step a semiconductor substrate is provided, on which the integrated memory device is formed. In a next step, an FEOL processing of the semiconductor substrate is conducted to form memory cells, including a capacitor element and a transistor element. In a next step, a diffusion barrier is provided, wherein the diffusion barrier covers the substrate with the memory cells.

In a next step, the invention provides an isolation layer with a highly UV absorbing component. The isolation layer is adjacent to the diffusion barrier and may serve planarization purposes and provide a smooth device surface for subsequent processing by filling grooves and trenches, as well as electrically isolating the underlying electronic entities.

Via providing an isolation layer with a highly UV absorbing component, the invention does not require additional process stages, while still ensuring a sufficient blocking of ultra violet light. In a subsequent MOL/BEOL processing of the semiconductor substrate, which then already comprises the memory cells, the diffusion barrier, and the isolation layer with the highly UV absorbing component, again a wiring of the memory cells is provided.

In the invention, an isolation layer with a highly UV absorbing layer allows for the fabrication of an integrated memory device with an enhanced data retention time. Furthermore, no additional process stages are required and the number of process stages may be kept constant.

The reliability and the overall performance of the integrated memory device may be enhanced, while avoiding changes of an established and, therefore, very efficient fabrication process.

According to a yet another embodiment of the present invention, an integrated circuit is provided, which is formed on a semiconductor substrate. The integrated circuit comprises FEOL processed electronic elements and BEOL processed wiring on top of the electronic elements for interconnecting the electronic elements. Additionally, a highly UV absorbing layer is provided between the electronic elements and the wiring.

The inventive highly UV absorbing layer permits MOL/BEOL processing, which may also comprise process stages during which the already formed parts of the integrated circuit are exposed to high energy ultra violet light. The highly UV absorbing layer screens parts which are already formed on the semiconductor substrate, and hence prevents disadvantageous modifications, particularly the formation of a localized enhancement of the electronic density of states.

According to the present invention, the integrated circuit may take full advantage out of a higher integration of electronic elements, due to a reduction of sources of undesired currents and signal noise. The suppression of undesired localized enhancements of the electronic density of states results in a reduced minimum size of the functional electronic elements, and hence to an integrated circuit with an increased overall performance.

According to another embodiment of the present invention, there is an integrated memory device which is formed on a semiconductor substrate. The integrated memory device comprises FEOL processed memory cells and a BEOL processed wiring on top of the memory cells for interconnecting the memory cells. Between the memory cells and the wiring, the integrated memory device comprises an MOL processed diffusion barrier and a highly UV absorbing layer. The highly UV absorbing layer is arranged adjacent to the diffusion barrier.

In this way, the integrated memory device may be manufactured by the use of an FEOL, an MOL, and a BEOL of a CMOS manufacturing process and may take full advantage out of a higher integration of its memory cells. The suppression of undesired localized enhancements of the electronic density of states results in a reduced minimum size of the functional memory cells, and hence to an integrated memory device with an increased memory capacity and an improved data retention time.

According to still another embodiment of the present invention, an integrated memory device is provided, which is formed on a semiconductor substrate. The integrated memory device comprises FEOL processed memory cells and BEOL processed wiring on top of the memory cells for interconnecting the memory cells. Between the memory cells and the wiring, the integrated memory device comprises an MOL processed diffusion barrier and an isolation layer which comprises a highly UV absorbing component. The isolation layer is arranged adjacent to the diffusion barrier. In this way, electric isolation and absorption of ultra violet light is achieved by a single layer, without the need for additional layers or coatings. According to an embodiment of the present invention, the highly UV absorbing layer comprises silicon-oxy-nitride. This material may be deposited by established deposition techniques, being already a reproducible and tested part of a modern CMOS fabrication process.

Silicon-oxy-nitride is furthermore able to absorb ultraviolet light. Preferably, according to a next embodiment, the silicon content of said highly UV absorbing layer, ranges from 40 to 99 atomic percent. Silicon-oxy-nitride with a silicon content of the range proved to be advantageous, due to its absorption of ultra violet light.

According to still another embodiment of the present invention, the highly UV absorbing layer comprises at least one of hafnium-silicon-oxy-nitride, hafnium-titanium-oxide, praseodymium-oxide, lanthanum-oxide, or lanthanum-aluminum-oxide. According to this embodiment, the addition of at least one of the materials into the-highly UV absorbing layer substantially increases the UV light absorption properties of the highly UV absorbing layer. Further, the materials may be deposited by means of reproducible and well established techniques of modern fabrication processes of integrated circuits and integrated memory devices.

According to another embodiment of the present invention, the thickness of the highly UV absorbing layer ranges from 5 to 30 nm. A thickness in the range does provide sufficient UV light absorption, while being thin enough for not changing the overall device or circuit structure.

According to yet another embodiment of the present invention, the highly UV absorbing layer absorbs ultraviolet light with wavelengths below 400 nm. Such ultra violet light is both mainly caused by the MOL/BEOL processing and responsible for undesired modifications of electronic entities, such as capacitors, transistors, or other related electronic elements, at interfaces of materials with different electronic properties.

According to still another embodiment of the present invention, the highly UV absorbing layer reduces the intensity of the ultraviolet light by at least 30%. The absorption is high enough for substantially improving device reliability and performance due to a reduced generation of an undesired enhancement of an electronic density of states. In this way, sources of undesired currents and a worsening of signal accuracy may be reduced by an absorption of at least 30% of ultra violet light.

According to a further embodiment of the present invention, a diffusion barrier is provided which comprises silicon-nitride. The material may be deposited by established and reproducible deposition techniques, preferably by means of a low pressure chemical vapor deposition (LP-CVD) process. Silicon-nitride is also suitable for blocking the diffusion of materials which are deposited during later method stages and which may cause a reduction of the functionality of electronic entities, such as transistor elements.

According to yet another embodiment of the present invention, an isolation layer on the semiconductor substrate is provided. The isolation layer includes a highly UV absorbing component for absorbing ultra violet light. Further, the isolation layer is arranged adjacent to the diffusion barrier. According to this embodiment, two functionalities may be combined and be provided simultaneously by one layer. Whereas the isolation layer may provide electric isolation of the underlying electronic entities and a passivation of the structured semiconductor substrate, the absorbing component of the isolation layer provides the absorption of ultra violet light. Hence, both functionalities may be provided by one element, which may be provided in a single process stage.

The isolation layer, including the highly UV absorbing component, may preferably comprise boron-phosphate-silicate-glass (BPSG). The deposition and structuring of BPSG is a highly established technique in modem fabrication processes for integrated circuits and integrated memory devices. Since a BPSG element is already part of most fabrication processes, the inventive addition of a highly UV absorbing component to the BPSG element provides a very efficient provision of an UV absorbing element.

According to another embodiment of the present invention, the isolation layer is fabricated by means of a co-deposition of boron-phosphate-silicate-glass and impurity atoms. These impurity atoms then act as color centers for absorbing radiation in the range of respective ultra violet wavelengths. Preferably, the impurity atoms are from one of the rare earth elements. Furthermore, the impurity atoms may be from one of the transition metal elements.

According to another embodiment of the present invention, the impurity atoms may be in their 3+ oxidation state. Preferably, the contents of the impurity atoms in the isolation layer ranges from 0.05% to 2%. The impurity atoms of the elements in the oxidation state and the concentration form a preferable absorption component, which sufficiently absorbs ultra violet light. The impurity atoms therefore protect underlying sensitive electronic entities from being disadvantageously modified by the high energy ultra violet light.

According to a further embodiment of the present invention, the isolation layer, including a highly UV absorbing component, is deposited by means of a co-deposition of boron-phosphate-silicate-glass and a metal organic precursor. With use of a metal organic precursor, the integration of a highly UV absorbing component can be achieved very efficiently, while the overall co-deposition process may be integrated in a modern fabrication process for integrated circuits and integrated memory devices. Preferably, the metal organic precursors comprise erbium-isopropoxide and/or neodymium-isopropoxide. The precursors are suitable for the integration of the rare earth impurity atoms into the BPSG during an established deposition process.

### BRIEF DESCRIPTION OF THE DRAWINGS

The present invention will be described below in more details with reference to the embodiments and drawings, in which:

FIG. 1 shows an integrated circuit during process stages A through E, according to a first embodiment of the present invention.

FIG. 2 shows an integrated circuit during process stages A through E, according to a second embodiment of the present invention.

FIG. 3 shows an integrated memory device, according to a third embodiment of the present invention.

FIG. 4 shows an integrated memory device, according to a fourth embodiment of the present invention.

FIG. 5 shows an integrated memory device, according to a fifth embodiment of the present invention.

FIG. 6 shows an integrated memory device, according to a sixth embodiment of the present invention.

### DETAILED DESCRIPTION OF THE INVENTION

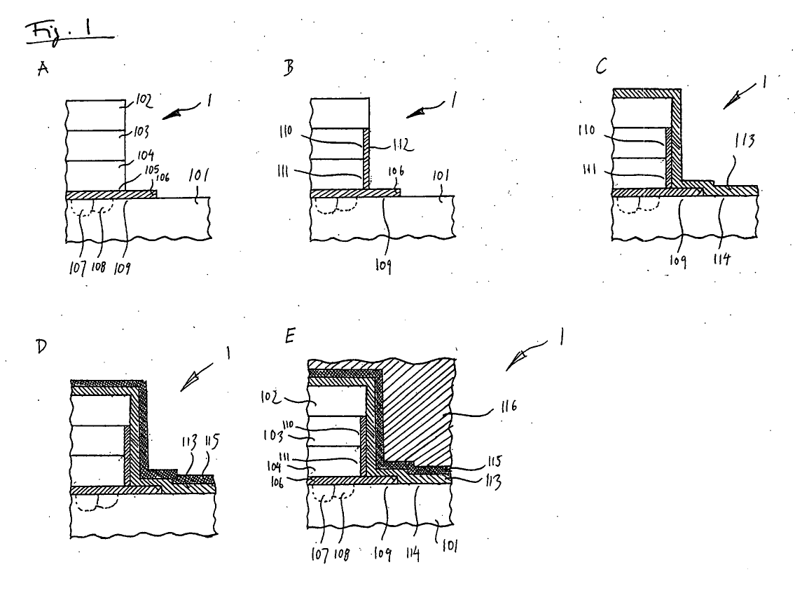

FIG. 1 shows a section of an integrated device 1 as a schematic view. As shown in panel A, the integrated device 1 is formed on a semiconductor substrate 101 comprising doped regions 107, 108. The doped regions 107 and 108 may be part of a transistor, a resistor, a capacitor, or another related electronic entity. The substrate 101 is covered in part by an isolation layer 106. On top of the isolation layer 106 three elements 102, 103, and 104 are structured, which may comprise a semiconductor, a metal, an alloy, or a composite material. These elements 102, 103, and 104 may form a so-called gate stack in an integrated memory device. In this case, the lower part 104 may comprise poly-silicon, the center part 103 a metal-silicon alloy, such as tungsten-silicide (WSi), and the upper part 102 may comprise an insulator, such silicon-nitride (Si₃N₄).

The elements 102, 103, and 104 may be isolated from underlying electronic entities, such as the doped regions 107 and 108, or may also be in electric contact with electronic entities formed below them. The isolation layer 106 forms interfaces 105 and 109 toward a semiconductor element, such as the semiconductor substrate 101, or toward the element 104, which may comprise a semiconductor, a metal, an alloy, or a composite material.

In a next process step, as illustrated in panel B, parts of the elements 101, 103, and 104 are modified to form a second isolation layer 112. This second isolation layer 112 may be formed by oxidizing parts of the elements 101, 103, and 104, to form an isolating oxide layer. New interfaces 110, 111, and 114 are herewith formed.

Panel C shows the section of the integrated device I after a next process step, during which a diffusion barrier 113 was provided. This diffusion barrier 113 prevents material to diffuse to, in this case, underlying electronic entities. Since the diffusion barrier is often also electrically isolating, the diffusion barrier 113 is also an isolation layer.

In a subsequent step, as shown in panel D, a highly UV absorbing layer 115 is formed on top of the diffusion layer 113. The highly UV absorbing layer 115 absorbs ultra violet light, preferably, with wavelengths below 400 nm, and at least with an absorption of 30%. In this way, ultra violet light which is generated above the absorbing layer 115 may not penetrate through the highly UV absorbing layer 115 to cause a disadvantageous modification at interfaces of isolation elements toward other materials, such as the interfaces 109 through 111, or 114.

At the interfaces ultra violet light may enhance the electronic density of states, and ultimately undesired generation/recombination currents. Such currents may reduced reduce the reliability of said electronic entities and diminishes the overall performance of the integrated circuit.

By the inventive addition of the highly UV absorbing layer 115, ultra violet light is attenuated, such that disadvantageous modifications below the highly UV absorbing layer 115 are sufficiently suppressed.

Eventually, panel E shows a schematic view of the integrated circuit 1 after formation of a third isolation layer 116. This third isolation layer 116 usually comprises an isolating glass, such as boron-phosphate-silicate-glass (BPSG), which, besides isolating the underlying structures, also fills up voids and provides a planarization of the integrated circuit 1 for further processing.

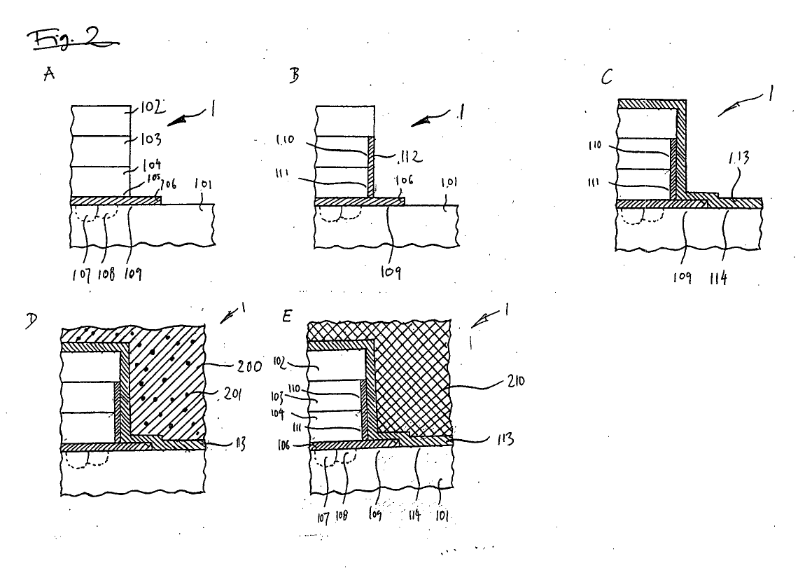

FIG. 2 shows a section of the integrated device 1 as a schematic view, according to a second embodiment of the present invention. As shown in panel A through C, the integrated device 1 is formed by the same process stages according to the first embodiment of the present invention, as described with conjunction of FIG. 1.

However, according to this second embodiment of the present invention, a fourth isolation layer 200 with a highly UV absorbing component 201 is formed on top of the diffusion layer 113 during a subsequent step, as shown in panel D. The highly UV absorbing component 201 absorbs ultra violet light, preferably, with wavelengths below 400 nm, and at least with an absorption of 30%. In this way, ultra violet light which is generated above the isolation layer 200 with the highly UV absorbing component 201 may not penetrate to underlying elements to cause a disadvantageous modification at interfaces of isolation elements toward other materials.

Panel E shows the integrated device 1 after an annealing of the isolation layer 200 with the highly UV absorbing component 201 to form a stable highly UV absorbing element 210.

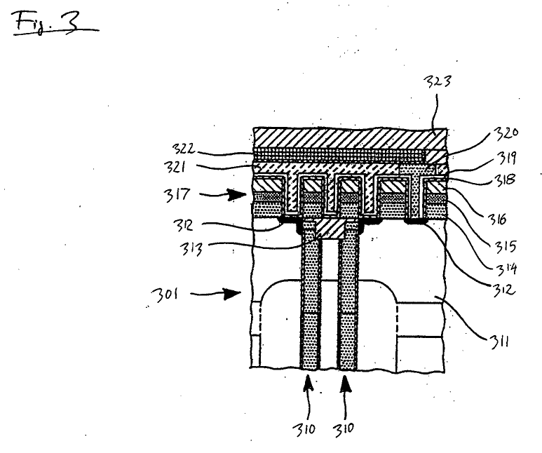

FIG. 3 shows a schematic view of a section of an integrated memory device. The integrated memory device comprises electronic entities, such as trench capacitors 310 formed mainly in a semiconductor substrate 301, doped regions 312 of the semiconductor substrate forming an entire transistor element, or a part thereof, and other electronic entities on top of the semiconductor substrate 301. Electronic entities above the substrate 301 include entities such as a gate stack 317, comprising a poly-silicon element 314, a silicide element 315, and a silicon-nitride element 316. The silicide element 315 may comprise a composition of tungsten and silicon.

A diffusion barrier 318 covers partially the electronic entities and forms the barrier for the undesired diffusion of material toward the highly sensitive electronic entities, such as the doped semiconductor regions 312. The diffusion barrier 318 only has perforations at regions where a contact from above must be established to sections of the underlying electronic elements. For example, a vertical contact 320 may establish an electric contact from a BEOL wiring 322 to an electronic entity formed in or above the semiconductor substrate 301, such as the respective doped region 312. Neighboring electronic entities, such as the two trench capacitors 310, may be separated and electrically isolated by an isolation layer 313. Furthermore, the integrated memory device may comprise a top passivating layer 323, for protection and electric isolation of the integrated circuitry.

The integrated memory device further comprises a highly UV absorbing layer 319 adjacent to the diffusion barrier 318. In this way, electronic entities are screened from high energy ultra violet light, to which they may be exposed during a MOL/BEOL processing of, for example, a wiring 322. Since ultra violet light is sufficiently blocked by the highly UV absorbing layer 319, a modification of the electronic elements below is suppressed.

Ultra violet light may cause an increased density of electronic states at interfaces between two different materials, preferably at interfaces between an insulator and a semiconductor or between an insulator and a semiconductor-metal alloy. Local enhancements of the electronic density of states ultimately result in undesired generation/recombination currents, which cause a reduction in the data retention time. A reduced data retention time of an integrated memory device strongly affects and reduces the overall performance of such an electronic memory device. Hitherto employed integrated memory devices therefore maintain a sufficiently large component size for compensating for an uncontrolled and undesired spatial enhancement of the density of electronic states.

With the inventive addition of a highly UV absorbing layer 319, integration can be drawn further, the minimum size of the electronic elements can be reduced, the number of memory cells on a chip can be increased, and, in summary, the invention allows for an enhancement of the overall performance of integrated memory devices and other integrated device, where integration is directly related to the device performance.

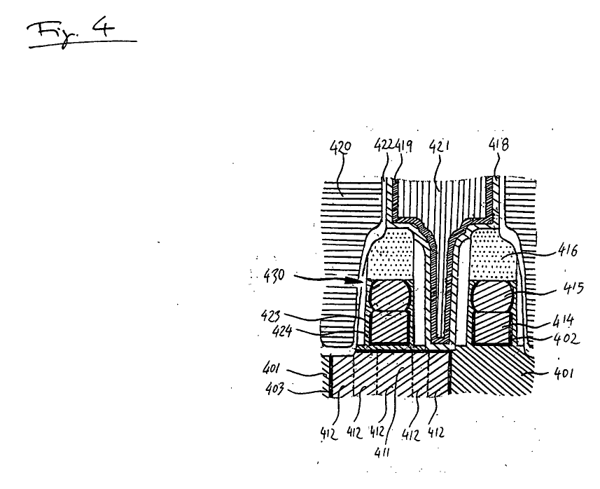

FIG. 4 shows a detailed schematic view of an integrated memory device according to a fourth embodiment of the present invention. A gate stack 430 comprises a poly-silicon element 414, a silicide element 415, and a silicon-nitride element 416. Furthermore, a transistor element 411 comprises doped regions of a semiconductor 412. An isolation layer 401 separates adjacent electronic elements.

Interfaces between an isolator and a semiconductor, and an isolator and a conductor respectively, are formed, as shown here, between the semiconductor element 411 and the isolation layer 401, between the poly-silicon element 414 and the isolation layer 401, between the silicide element 415 and the isolation layer 401, and between the respective parts of the left gate stack and the respective isolation layer 424. These interfaces are denoted by 402, 403 and 423. Electric contact to the electronic elements may be established by vertical conducting lines 420. A diffusion barrier 418 prevents material to diffuse toward sensitive elements, such as the doped regions 412 of the semiconductor.

The integrated memory device further comprises a highly UV absorbing layer 419, which covers sensitive electronic elements, such as the gate stack 430 or the transistor element 411.

According to this embodiment, isolator-semiconductor interfaces, or isolator-conductor interfaces, are screened from ultraviolet light by the highly UV absorbing layer 419.

After the formation of the electronic elements, the integrated memory device may be processed by a full range of MOL/BEOL processes, also including processes that expose the device to ultra violet light, without causing the undesired enhancement of the electronic density of states at interfaces or other related disadvantageous modifications. Above an MOL processed isolation layer 421, mainly the device wiring and other passivating layers are formed during an MOL/BEOL of a CMOS fabrication process.

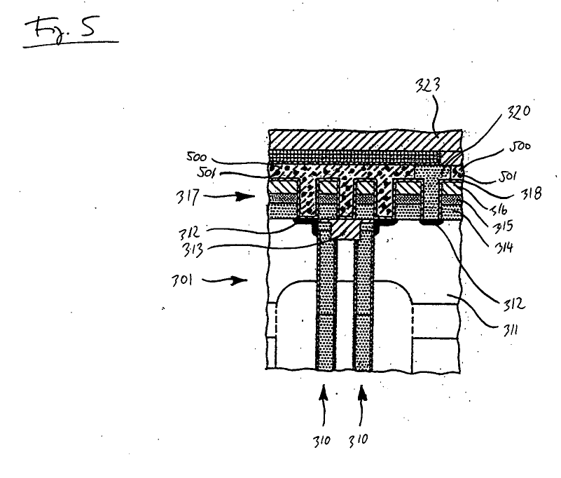

FIG. 5 shows a schematic view of a section of an integrated memory device, according to a fifth embodiment of the present invention. Since the integrated memory device, according to this embodiment, is similar to the device described in FIG. 3, not all elements are described anew and are denoted by identical reference signs.

The integrated memory device, according to this fifth embodiment, further comprises an isolation layer 500 with a highly UV absorbing component 501, the isolation layer 500 being adjacent to the diffusion barrier 318.

With the inventive addition of a highly UV absorbing component 501 to the isolation layer 500, both a screening of sensitive electronic elements from ultra violet light and an electrical isolation of said elements can be realized by only one layer of the device simultaneously.

In this way, no additional element has to be added to the device, and, since the highly UV absorbing component 501 may be co-deposited during the deposition of the isolation layer 500, no additional process steps have to be conducted. However, the material system of the isolation layer 500 and the component 501 may be annealed after co-deposition for further stability and activation.

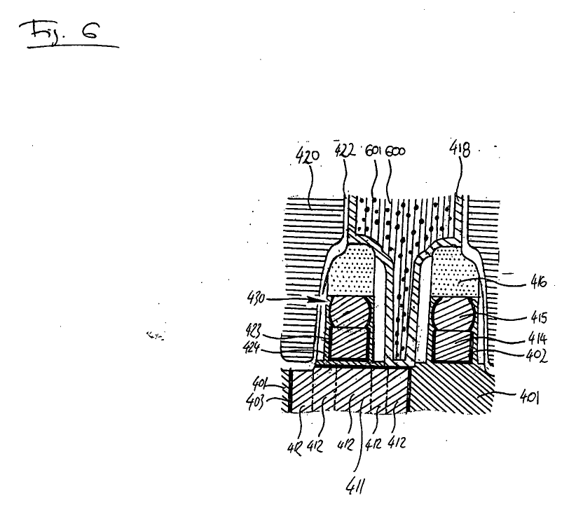

FIG. 6 shows a detailed schematic view of an integrated memory device according to a sixth embodiment of the present invention. Since the integrated memory device according to this embodiment is similar to the device described in FIG. 4, not all elements are described anew.

The integrated memory device, according to this sixth embodiment, further comprises an isolation layer 600 with a highly UV absorbing component 601, the isolation layer 600 being adjacent to the diffusion barrier 418. The material system of the isolation layer 600 and the component 601 may be annealed after co-deposition for further stability and activation.

The preceding description only describes advantageous exemplary embodiments of the invention. The features disclosed therein and the claims and the drawings can, therefore, be essential for the realization of the invention in its various embodiments, both individually and in any combination.

What is claimed is:

1. A method for fabricating an integrated circuit, comprising:
providing a semiconductor substrate;
front-end-of-line processing of the semiconductor substrate to form electronic elements;
providing a highly UV-absorbing layer on the semiconductor substrate, the highly UV-absorbing layer covering the electronic elements; and
back-end-of-line processing of the semiconductor substrate, comprising the electronic elements and the highly UV-absorbing layer on top, to provide a wiring of the electronic elements.

2. The method as claimed in claim 1, wherein the highly UV-absorbing layer comprises silicon-oxy-nitride.

3. The method as claimed in claim 2, wherein the silicon content of the highly UV-absorbing layer ranges from 40 to 99 atomic percent.

4. The method as claimed in claim 1, wherein the highly UV-absorbing layer comprises at least one of:
hafnium-silicon-oxy-nitride,
hafnium-titanium-oxide,
praseodymium-oxide,
lanthanum-oxide, and
lanthanum-aluminum-oxide.

5. The method as claimed in claim 1, wherein the thickness of the highly UV-absorbing layer ranges from 5 to 30 nm.

6. The method as claimed in claim 5, wherein the highly UV-absorbing layer absorbs UV light with wavelengths below 400 nm.

7. The method as claimed in claim 6, wherein the highly UV-absorbing layer reduces the intensity of the UV light by at least 30 per cent.

8. The method for fabricating an integrated memory device, comprising:
providing a semiconductor substrate;
front-end-of-line processing of the semiconductor substrate to form memory cells, the memory cells each including a capacitor element and a transistor element;
providing a diffusion barrier, the diffusion barrier covering the memory cells;
providing a highly UV-absorbing layer on the semiconductor substrate, the highly UV-absorbing layer being adjacent to the diffusion barrier; and
back-end-of-line processing of the semiconductor substrate, comprising the memory cells with the diffusion barrier and the highly UV-absorbing layer on top, to provide a wiring of the memory cells.

9. The method as claimed in claim 8, wherein the diffusion barrier comprises silicon-nitride.

10. The method as claimed in claim 8, wherein the diffusion barrier is deposited by means of a low pressure chemical vapor deposition process.

11. The method as claimed in claim 8, wherein the highly UV-absorbing layer comprises silicon-oxy-nitride.

12. The method as claimed in claim 11, wherein the silicon content of the highly UV-absorbing layer ranges from 40 to 99 atomic percent.

13. The method as claimed in claim 8, wherein the highly UV-absorbing layer comprises at least one of:
hafnium-silicon-oxy-nitride,
hafnium-titanium-oxide,
praseodymium-oxide,
lanthanum-oxide, and
lanthanum-aluminum-oxide.

14. The method as claimed in claim 8, wherein the thickness of the highly UV-absorbing layer ranges from 5 to 30 nm.

15. The method as claimed in claim 14, wherein the highly UV-absorbing layer absorbs UV light with wavelengths below 400 nm.

16. The method as claimed in claim 15, wherein the highly UV-absorbing layer reduces the intensity of the UV light by at least 30 per cent.

17. A method for fabricating an integrated memory device, comprising:
providing a semiconductor substrate;
front-end-of-line processing of the semiconductor substrate to form memory cells, the memory cells each including a capacitor element and a transistor element;
providing a diffusion barrier, the diffusion barrier covering the memory cells;
providing an isolation layer on the semiconductor substrate, the isolation layer including a highly UV-absorbing component and being adjacent to the diffusion barrier; and
back-end-of-line processing of the semiconductor substrate, comprising the memory cells with the diffusion barrier and the isolation layer on top, to provide a wiring of the memory cells.

18. The method as claimed in claim 17, wherein the diffusion barrier comprises silicon-nitride.

19. The method as claimed in claim 17, wherein the diffusion barrier is deposited by means of a low pressure chemical vapor deposition process.

20. The method as claimed in claim 17, wherein the isolation layer, including a highly UV-absorbing component, comprises boron-phosphate-silicate-glass.

21. The method as claimed in claim 20, wherein the isolation layer, including a highly UV-absorbing component, is deposited by means of a co-deposition of boron-phosphate-silicate-glass and impurity atoms.

22. The method as claimed in claim 21, wherein the impurity atoms are at least from one of the rare earth elements.

23. The method as claimed in claim 21, wherein the impurity atoms are at least from one of the transition metal elements.

24. The method as claimed in claim 22, wherein the atoms of the elements are in their 3+ oxidation state.

25. The method as claimed in claim 23, wherein the atoms of the elements are in their 3+ oxidation state.

26. The method as claimed in claim 21, wherein the contents of the impurity atoms in the isolation layer ranges from 0.0to 2%.

27. The method as claimed in claim 21, wherein the isolation layer, including a highly UV-absorbing component, is deposited by means of a co-deposition of boron-phosphate-silicate-glass and a metal-organic precursor.

28. The method as claimed in claim 27, wherein the metal-organic precursor comprises at least one of:
erbium-isopropoxide [Er(OCH(CH₃)₂)₃], and
neodymium-isopropoxide [Nd(OCH(CH₃)₂)₃].

29. The method as claimed in claim 17, wherein the isolation layer, including a highly UV-absorbing component, absorbs UV light with wavelengths below 400 nm.

30. The method as claimed in claim 29, wherein the isolation layer, including a highly UV-absorbing component, reduces the intensity of the UV light by at least 30 per cent.

31. An integrated circuit formed on a semiconductor substrate, comprising:
front-end-of-line processed electronic elements; and
a back-end-of-line processed wiring on top of the electronic elements, the wiring interconnecting the electronic elements, wherein a highly UV-absorbing layer is provided between the electronic elements and the wiring.

32. The integrated circuit as claimed in claim 31, wherein the highly UV-absorbing layer silicon-oxy-nitride.

33. The integrated circuit as claimed in claim 32, wherein the silicon content ranges from 40 to 99 atomic percent.

34. The integrated circuit as claimed in claim 31, wherein the highly UV-absorbing layer comprises at least one of:
hafnium-silicon-oxy-nitride,
hafnium-titanium-oxide,
praseodymium-oxide,
lanthanum-oxide, and
lanthanum-aluminum-oxide.

35. The integrated circuit as claimed in claim 31, wherein the thickness of the highly UV-absorbing layer ranges from 5 to 30 nm.

36. The integrated circuit as claimed in claim 31, wherein the highly UV-absorbing layer absorbs UV light with wavelengths below 400 nm.

37. The integrated circuit as claimed in claim 36, wherein the highly UV-absorbing layer reduces the intensity of the UV light by at least 30 per cent.

38. An integrated memory device formed on a semiconductor substrate, comprising:
front-end-of-line processed memory cells, a diffusion barrier on top of the memory cells; and
a back-end-of-line processed wiring on top of the diffusion barrier, the memory cells each comprising a capacitor element and a transistor element, the diffusion barrier covering the memory cells, and the wiring interconnecting the memory cells, wherein a highly UV-absorbing layer is provided between the diffusion barrier and the wiring.

39. The integrated memory device as claimed in claim 38, wherein the diffusion barrier comprises silicon-nitride.

40. The integrated memory device as claimed in claim 38, wherein the highly UV-absorbing layer comprises silicon-oxy-nitride.

41. The integrated memory device as claimed in claim 38, wherein the silicon content ranges from 40 to 99 atomic percent.

42. The integrated memory device as claimed in claim 38, wherein the highly UV-absorbing layer comprises at least one of:
hafnium-silicon-oxy-nitride,
hafnium-titanium-oxide,
praseodymium-oxide,
lanthanum-oxide, and
lanthanum-aluminum-oxide.

43. The integrated memory device as claimed in claim 38, wherein the thickness of the highly UV-absorbing layer ranges from 5 to 30 nm.

44. The integrated memory device as claimed in claim 38, wherein the highly UV-absorbing layer absorbs UV light with wavelengths below 400 nm.

45. The integrated memory device as claimed in claim 44, wherein the highly UV-absorbing layer reduces the intensity of the UV light by at least 30 per cent.

46. An integrated memory device formed on a semiconductor substrate, comprising:
front-end-of-line processed memory cells, a diffusion barrier on top of the memory cells, an isolation layer on top of the diffusion barrier; and
a back-end-of-line processed wiring on top of the isolation layer, the memory cells each comprising a capacitor element and a transistor element, the diffusion barrier covering the memory cells, and the wiring interconnecting said memory cells, wherein the isolation layer comprises a highly UV-absorbing component.

47. The integrated memory device as claimed in claim 46, wherein the diffusion barrier comprises silicon-nitride.

48. The integrated memory device as claimed in claim 46, wherein the isolation layer comprises boron-phosphate-silicate-glass.

49. The integrated memory device as claimed in claim 46, wherein the highly UV-absorbing components comprise at least one from the rare earth elements.

50. The integrated memory device as claimed in claim 46, wherein the highly UV-absorbing components comprise at least one from the transition metal elements.

51. The integrated memory device as claimed in claim 49, wherein the atoms of the elements are in their 3+ oxidation state.

52. The integrated memory device as claimed in claim 50, wherein the atoms of the elements are in their 3+ oxidation state.

53. The integrated memory device as claimed in claim 46, wherein the contents of the highly UV-absorbing component in the isolation layer ranges from 0.05% to 2%.

54. The integrated memory device as claimed in claim 46, wherein the highly UV-absorbing component absorbs UV light with wavelengths below 400 nm.

55. The integrated memory device as claimed in claim 54, wherein the highly UV-absorbing component reduces the intensity of the UV light by at least 30 per cent.
